(19) United States
(12) Patent Application Publication
(10) Pub. No.: US 2007/0072562 A1
(43) Pub. Date: Mar. 29, 2007

(54) Wireless communication module, wireless communication apparatus having wireless communication module, and control method thereof

(75) Inventor: Chee-hwan Yang, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/524,966

(22) Filed: Sep. 22, 2006

(30) Foreign Application Priority Data
Sep. 27, 2005 (KR) 2005-90012

(51) Int. Cl. G01S 13/00; H03C 1/52

(52) U.S. Cl. 455/106; 342/22

(57) ABSTRACT

A wireless communication apparatus including: an antenna; a signal processor which processes and converts a radio frequency (RF) signal received from the antenna into a baseband signal; an antenna connector which interconnects the antenna and the signal processor; a connection check part which checks whether the antenna is connected properly to output a connection check signal; and a system part which receives the connection check signal and executes a predetermined routine according to whether the antenna is connected. Accordingly, an aspect of the present invention provides a wireless communication module capable of accurately detecting connection of an antenna without suffering influence of a test environment.

### CROSS-REFERENCE TO RELATED APPLICATION

This application claims the benefit of Korean Patent Application No. 2005-90012, filed on Sep. 27, 2005, in the Korean Intellectual Property Office, the disclosure of which is incorporated herein by reference.

### BACKGROUND OF THE INVENTION

1. Field of the Invention

Aspects of the present invention relate to a wireless communication module, a wireless communication apparatus having the wireless communication module, and a control method thereof, and more particularly, to a wireless communication module which checks whether an antenna is normally connected, a wireless communication apparatus having the wireless communication module, and a control method thereof.

2. Description of the Related Art

A typical wireless communication module embedded in a wireless communication apparatus employs an internal antenna of a Planar Inverted-F Antenna (PIFA) type. Whether the antenna is normally connected is checked in an assembly phase of the wireless communication apparatus or in follow-up services.

A typical connection check between the conventional wireless communication apparatus and the antenna in a portable computer is now described with reference to FIGS. 1A and 1B.

As shown in FIG. 1A, a communication module embedded in a portable computer includes an antenna 1, a radio frequency (RF) circuit 2 coupled to the antenna 1, and a baseband media access control (MAC) circuit 3. The antenna 1 transmits or receives an RF signal over the air. The RF circuit 2 transmits to the antenna 1 and receives from the antenna 1 the RF signal. The baseband MAC circuit 4 processes data in association with the RF circuit 2. The processed signals are provided to a system 4 via a host interface.

The communication module of the related art checks whether the antenna 1 is normally connected by checking the signal intensity against a reference value. To this end, the RF circuit 2 measures the intensity of the signal received over the antenna 1 from an access point 5 which periodically transmits an RF signal from outside the system 4, and the baseband MAC circuit 3 transmits the information about the signal intensity to the system 4 via the host interface.

Since the RF signal is transmitted along paths in unspecified directions, the RF signal transmitted from the access point 5 arrives at the antenna 1 through scattering, diffraction, reflection, absorption and the like. Hence, the received signal varies in real-time and is considerably affected by environment.

Additionally, as the signal characteristic changes according to a reception location of the antenna 1, accurately measuring the signal intensity requires securely installing a transmitter and a receiver at fixed locations within an anechoic chamber.

However, it is difficult to apply such a test environment to portable computers one-by-one at the manufacturing phase of a mass production. Thus, as shown in FIG. 1B, the signal intensity is measured using the embedded wireless module while portable computers are arranged on racks (A) or on a conveyor belt (B).

For example, where the reference value is SNR 20 dB, the normal connection of the antenna 1 is determined when the measured signal intensity is greater than 20 dB. When the measured signal intensity is less than 20 dB, the abnormal connection of the antenna 1 is determined.

Yet, the related art cannot ensure reliability of the connection check of the antenna 1 because the intensity of the received signal varies as time passes by, even when the test is conducted at the same location. Moreover, if the same reference value is applied while locations of test samples are different from one another, the test reliability is further degraded.

### SUMMARY OF THE INVENTION

Accordingly, it is an aspect of the present invention to provide a wireless communication module capable of accurately detecting a connection of an antenna without suffering the influence of a test environment.

Additional aspects and/or advantages of the invention will be set forth in part in the description which follows and, in part, will be obvious from the description, or may be learned by practice of the invention

According to an aspect of the present invention, there is provided a wireless communication apparatus comprising: an antenna; a signal processor which processes and converts a radio frequency (RF) signal received from the antenna into a baseband signal; an antenna connector which interconnects the antenna and the signal processor; a connection check part which checks whether the antenna is connected properly and outputs a connection check signal; and a system part which receives the connection check signal and executes a predetermined routine according to whether the antenna is connected properly.

The connection check part may, although not necessarily, be connected to an RF signal line through which the RF signal received at the antenna is transmitted to the signal processor, and the connection check part outputs the connection check signal according to an opening or a grounding of the RF signal line.

The system part may, although not necessarily, comprise a display part and a controller which controls to display a message informing whether the antenna is connected properly on the display part according to the predetermined routine.

The wireless communication apparatus may, although not necessarily, further comprise an interface which communicates data between the signal processor and the system part, wherein the connection check signal is provided to the system part through the interface by way of the signal processor.

The connection check signal may, although not necessarily, be provided to the system part through a signal output pin.

The signal processor may, although not necessarily, comprise an RF circuit which is connected with the antenna and transmits and receives the RF signal, and a baseband MAC circuit which processes and converts the RF signal received from the RF circuit into the baseband signal.

The connection check part may, although not necessarily, output the connection check signal to at least one of the baseband MAC circuit or a predetermined output pin connected to the system part.

According to another aspect of the present invention, there is provided a wireless communication apparatus comprising: a wireless communication module which comprises an antenna, a signal processor which processes and converts a radio frequency (RF) signal received from the antenna into a baseband signal, an antenna connector which interconnects the antenna and the signal processor, and a connection check part which checks whether the antenna is connected properly and outputs a connection check signal; and a system part which receives the connection check signal and executes a predetermined routine according to whether the antenna is connected properly.

The connection check part may, although not necessarily, be connected to an RF signal line through which the RF signal received at the antenna is transmitted to the signal processor, and the connection check part outputs the connection check signal according to an opening or a grounding of the RF signal.

The system part may, although not necessarily, comprise a display part and a controller which controls to display a message informing whether the antennal is connected properly on the display part according to the predetermined routine.

The wireless communication apparatus may, although not necessarily, further comprise an interface which communicates data between the signal processor and the system part, wherein the signal processor comprises: an RF circuit which is connected with the antenna and transmits and receives the RF signal; and a baseband MAC circuit which processes to convert the RF signal received from the RF circuit into the baseband signal.

The connection check part may, although not necessarily, output the connection check signal to at least one of the baseband MAC circuit or a predetermined output pin connected to the system part, and the baseband MAC circuit transmits the connection check signal to the system part through the interface.

According to yet another aspect of the present invention, there is provided a wireless communication module comprising: an antenna; a signal processor which processes and converts a radio frequency (RF) signal received from the antenna into a baseband signal; an antenna connector which interconnects the antenna and the signal processor; and a connection check part which checks whether the antenna is connected properly and outputs a connection check signal.

The connection check part may, although not necessarily, be connected to an RF signal line through which the RF signal received at the antenna is transmitted to the signal processor, and the connection check part outputs the connection check signal according to an opening or a grounding of the RF signal line.

The signal processor may, although not necessarily, comprise an RF circuit which is connected to the antenna and transmits and receives the RF signal, and a baseband MAC circuit which processes and converts the RF signal received from the RF circuit into the baseband signal.

The wireless communication module may, although not necessarily, further comprise an interface which communicates data with an external host, wherein the connection check part outputs the connection check signal to at least one of the baseband MAC circuit or a predetermined output pin connected to the external host, and the baseband MAC circuit transmits the connection check signal to the external host through the interface.

According to another aspect of the present invention, there is provided a method of controlling a wireless communication apparatus which comprises an antenna, a signal processor processing and converting a radio frequency (RF) signal received from the antenna into a baseband signal, an antenna connector interconnecting the antenna and the signal processor, and a system part receiving and processing the baseband signal, the method comprising: outputting a connection check signal with respect to the antenna according to an opening or a grounding of an RF signal line through which the RF signal received at the antenna is transmitted to the signal processor; and receiving, by the system part, the connection check signal and executing a predetermined routine according to whether the antenna is connected properly.

The system part may, although not necessarily, comprise a display part, and the executing of the predetermined routine comprises controlling to display a message informing whether the antenna is connected properly on the display part.

### BRIEF DESCRIPTION OF THE DRAWINGS

These and/or other aspects and advantages of the invention will become apparent and more readily appreciated from the following description of the embodiments, taken in conjunction with the accompany drawings, of which:

FIG. 1A is a block diagram of a portable computer of the related art;

FIG. 1B is a diagram to illustrate a test method of the portable computer of the related art;

FIG. 2 is a block diagram of a portable computer according to an embodiment of the present invention;

FIGS. 3A and 3B are detailed diagrams of the portable computer and a connection check part according to an embodiment of the present invention; and

FIG. 4 is a flow chart to explain control operations of the portable computer according to an embodiment of the present invention.

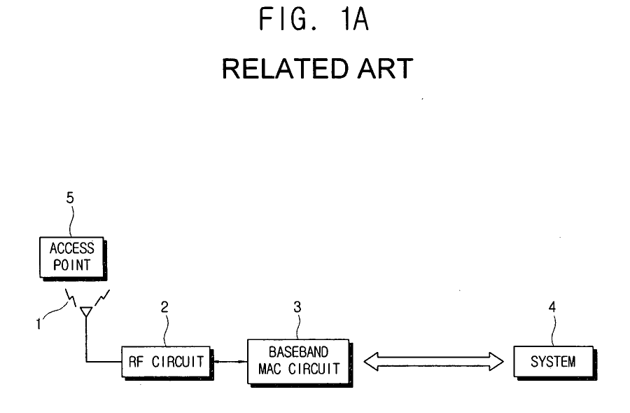

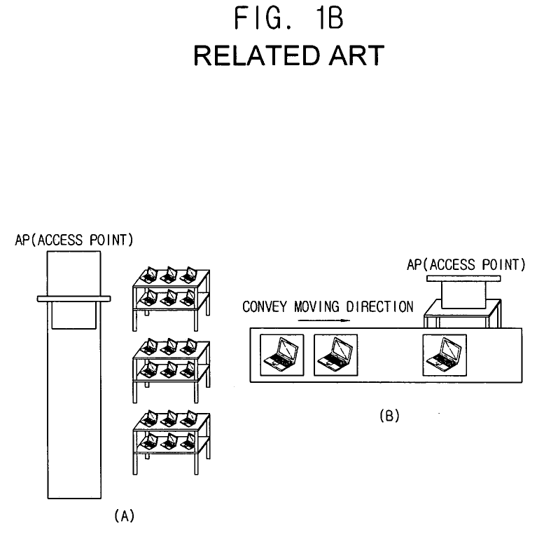

### DETAILED DESCRIPTION OF THE EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

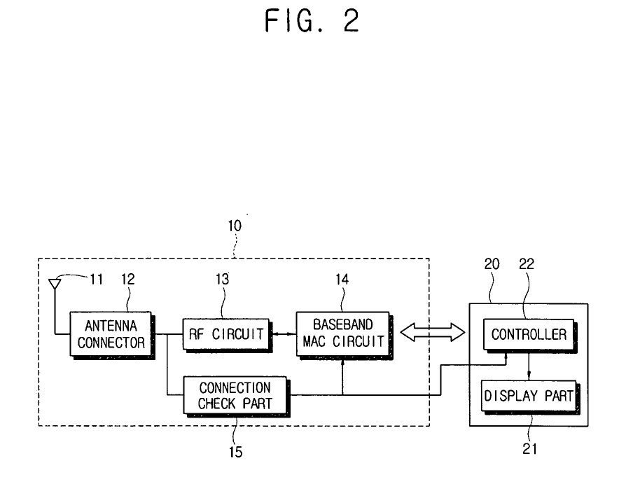

Descriptions are now provided of a wireless communication module and a portable computer having the wireless communication module according to an embodiment of the present invention with reference to FIG. 2.

The portable computer, as shown in FIG. 2, includes a wireless communication module 10 and a system part 20. The wireless communication module 10 receives and processes an RF signal to transmit the RF signal to the system part 20. The system part 20 processes the RF signal received from the wireless communication module 10 and displays the processed signal onto a screen or emits the processed signal in another way, such as by producing audio. The wireless communication module 10 and the system part 20 may, although not necessarily, communicate with each other via Peripheral Component Interconnect (PCI), PCI Express, and/or Universal Serial Bus (USB) interface.

The wireless communication module 10 includes an antenna 11, an RF circuit 13, and a baseband MAC circuit 14. The antenna 11 transmits or receives an RF signal over the air. The RF circuit 13 is coupled to the antenna 11, and transmits or receives the RF signal. The baseband MAC circuit 14 processes the signal output from the RF circuit 13. The signal processed by the baseband MAC circuit 14 is transmitted to the system part 20 via the PCI, the PCI Express, and/or the USB interface, as mentioned above.

In the embodiment of the present invention, the antenna 11 connects to an antenna connector 12, and the RF signal received at the antenna 11 is transmitted to the RF circuit 13 through the coaxial cable comprising an RF signal line and a ground line. In doing so, the antenna 11 embedded in the wireless communication module 10 serves as the antenna 11 at a high frequency to transmit and receive the RF signal, whereas the antenna 11 is shorted in a DC circuit, as a radiator of the antenna 11 and the ground are linked as one conductor.

In the embodiment of the present invention, the wireless communication module 10 further includes a connection check part 15. The connection check part 15 checks whether the antenna 11 is normally connected through the antenna connector 12. The connection check part 15 may be implemented as a circuit including a switching element.

The connection check part 15 is connected to the RF signal line, through which the RF signal is transmitted from the antenna 11. The connection check part 15 generates and outputs a connection check signal relating to the continuity of the antenna 11 by examining opening or short-circuiting in the DC circuit. The connection check signal output from the connection check part 15 may, although not necessarily, be transmitted to the system part 20 by way of the baseband MAC circuit 14 by a host interface and/or by allocating a separate output pin to the wireless communication module 10.

The connection check signal output from the connection check part 15 is transmitted to the system part 20. The system part 20 includes a controller 22 to receive the connection check signal of the antenna 11 and to execute a predetermined routine, and a display part 21 to display on a screen a message, generated by the controller 22, indicative of the connection of the antenna 11.

The controller 22 may, although not necessarily, be implemented using a microcontroller or a central processing unit (CPU) to control a graphic card to generate a connection check message based on the connection check signal according to a certain algorithm.

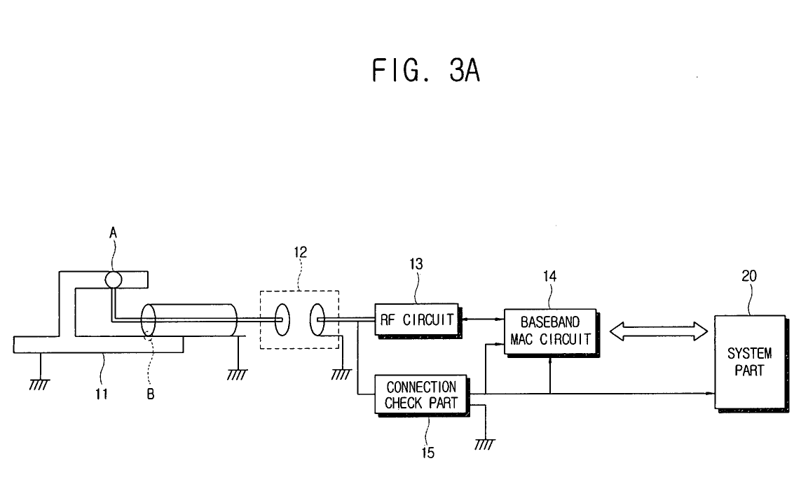

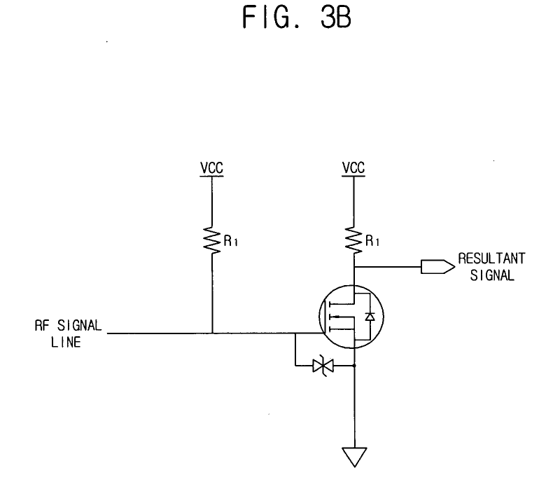

Further detailed descriptions are now made of the wireless communication module and the method of the connection check on the antenna of the portable computer with reference to FIGS. 3A and 3B.

FIG. 3A is a block diagram of the portable computer and the connection check part 15 according to an embodiment of the present invention.

Referring to FIG. 3A, a radiator contact point A and a ground contact point B of the antenna 11 are shorted by the coaxial cable comprising the RF signal line and the ground line. When the RF signal line from the antenna 11 is not connected to the RF circuit 13 because the antenna connector 12 is not normally coupled, the RF signal line is opened.

As shown in FIG. 3B, the connection check part 15 may include a switching element. In this case, when the RF signal line is opened, the connection check part 15 is turned on by a pull-up resistor, and then a resultant signal, i.e., the connection check signal, is output at a low level.

At this time, the connection check signal output from the connection check part 15 may, although not necessarily, be transmitted to the system part 20 by way of the baseband MAC circuit 14 through the host interface and/or the separate output pin of the wireless communication module 10. Accordingly, the system part 20 receiving the connection check signal outputs on the screen a message informing the abnormal connection of the antenna 11 according to a certain algorithm.

In contrast, when the antenna connector 12 is normally coupled and the RF signal line from the antenna 11 is connected to the RF circuit 13, the RF signal line is grounded. Specifically, as the low level signal is output from the RF signal line, the connection check part 15 is turned off and thus outputs a resultant signal, i.e., the connection check signal, at a high level.

Accordingly, the system part 20 receiving the connection check signal outputs on the screen a message indicating the normal connection of the antenna 11 according to a certain algorithm.

The connection check part 15 is a circuit affecting DC components which are opened or grounded by a simple low pass filter even when a signal is input to the RF signal line because the antenna 11 is short-circuited by the RF signal line and the ground line. The connection check part 15 is not limited to the description with reference to FIGS. 3A and 3B, and the connection check part may be variously implemented.

As such, the wireless communication module and the portable computer having the wireless communication module check whether the antenna is connected in the DC circuit using the characteristic of the antenna 11. Thus, it is possible to detect the antenna connection without influence of the test environment, and external test equipment, such as an access point, are unnecessary. In addition, since the antenna connection check method according to an embodiment of the present invention takes advantage of the electrical characteristics, the connection can be accurately detected even when it is difficult to confirm damage of the connector with the naked eye.

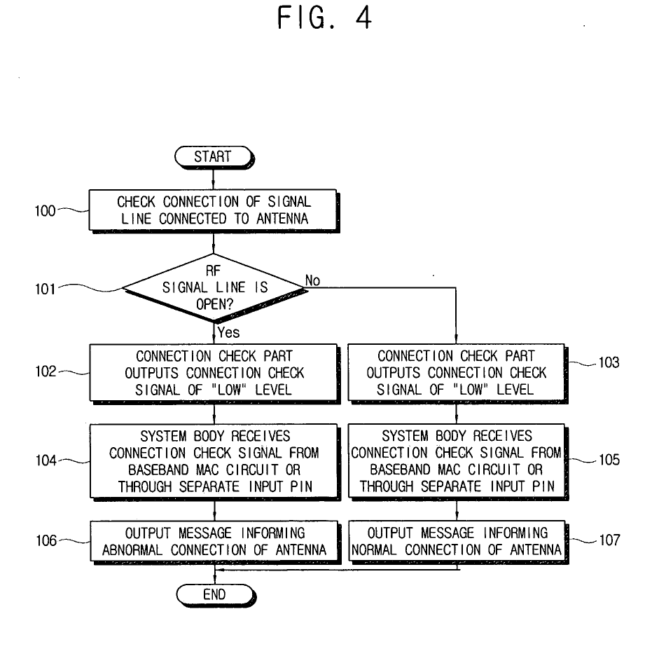

A control flow of the portable computer according to an embodiment of the present invention is explained below with reference to FIG. 4.

The connection check part 15 is connected to the RF signal line, through which the RF signal is transmitted from the antenna 11, and checks the connection of the antenna 11 by determining whether the RF signal line is opened or short-circuited in the DC circuit at operation 100.

More particularly, opening or short-circuiting of the RF signal line, to which both the antenna 11 and the RF circuit 13 are connected, is determined at operation 101. When the RF signal is opened, the connection check part 15 is turned on by the pull-up resistor and outputs the connection check signal at a low level at operation 102. When the antenna connector 12 is normally coupled, the RF signal line is grounded and thus the connection check part 15 is turned off and outputs the connection check signal at a high level at operation 103.

The system part 20 receives the connection check signal output from the connection check part 15 via the baseband MAC circuit 14 or a separate input pin at operation 104 or 105, and determines the connection of the antenna 11 based on the received connection check signal.

When the antenna 11 is not normally connected, the display part 21 may, although not necessarily, display a message informing the abnormal connection of the antenna 11 at operation 106. When the antenna 11 is normally connected, the display part 21 may, although not necessarily, display a message informing the normal connection of the antenna 11 at operation 107.

As such, the wireless communication apparatus of the present invention can test the connection of the antenna using the characteristic of the antenna at the assembly manufacturing phase or in follow-up services. Furthermore, the wireless communication apparatus can help to enhance the efficiency and the accuracy of the auto detection in a multi-antenna technique such as Multiple Input Multiple Output (MIMO), which is a next-generation wireless technology.

Although a portable computer is exemplified for better understanding, the present invention is also applicable to, but not limited to, IEEE 802.11 a/b/g, Bluetooth, and UWB wireless communication modules and wireless communication apparatuses using an antenna of which the radiator and the ground are short-circuited in the DC circuit. Although it has been explained that the connection check signal of the connection check part is provided to the system part via the baseband MAC circuit and/or a separate output pin, the connection check signal may, although not necessarily, be input to the RF circuit. The system part can inform the user of the antenna connection in manners other than displaying a message on the display part.

In view of the foregoing as set forth above, the wireless communication module, the wireless communication apparatus having the wireless communication module, and the control method thereof can accurately detect the antenna connection free from the effect of the test environment.

Although a few embodiments of the present invention have been shown and described, it will be appreciated by those skilled in the art that changes may be made in this embodiment without departing from the principles and spirit of the invention, the scope of which is defined in the claims and their equivalents.

What is claimed is:

1. A wireless communication apparatus comprising:
an antenna to transmit and/or to receive a radio frequency (RF) signal;
a signal processor to process and to convert the RF signal received from the antenna into a baseband signal;
an antenna connector to interconnect the antenna and the signal processor;
a connection check part to check whether the antenna is connected properly and to output a connection check signal; and
a system part to receive the connection check signal and to execute a predetermined routine according to whether the antenna is connected properly.

2. The wireless communication apparatus as claimed in claim 1, wherein the connection check part is connected to an RF signal line through which the RF signal received at the antenna is transmitted to the signal processor, and the connection check part outputs the connection check signal according to an opening or a grounding of the RF signal line.

3. The wireless communication apparatus as claimed in claim 2, further comprising a coaxial cable through which the antenna transmits the RF signal to the signal processor, wherein the coaxial cable comprises the RF signal line and a ground line.

4. The wireless communication apparatus as claimed in claim 2, wherein:
if the antenna is not connected properly, the RF signal line is opened, the connection check part is turned on, and the connection check signal is output at a first level; and
if the antenna is connected properly, the RF signal line is grounded, the connection check part is turned off, and the connection check signal is output at a second level opposite the first level.

5. The wireless communication apparatus as claimed in claim 1, wherein the system part comprises a display part to display a message to indicate whether the antenna is connected properly, wherein the predetermined routine generates the message.

6. The wireless communication apparatus as claimed in claim 1, further comprising:
a host interface to communicate data between the signal processor and the system part,
wherein the connection check signal is provided to the system part through the host interface by way of the signal processor.

7. The wireless communication apparatus as claimed in claim 1, wherein the connection check signal is provided to the system part through a signal output pin connected to the system part.

8. The wireless communication apparatus as claimed in claim 1, wherein the signal processor comprises an RF circuit which is connected to the antenna, and transmits and receives the RF signal.

9. The wireless communication apparatus as claimed in claim 8, wherein the signal processor further comprises a baseband MAC circuit to process and to convert the RF signal received from the RF circuit into the baseband signal.

10. The wireless communication apparatus as claimed in claim 9, wherein the connection check part outputs the connection check signal to the baseband MAC circuit, and the baseband MAC circuit transmits the connection check signal to the system part through a host interface.

11. A wireless communication module comprising:
an antenna to transmit and/or to receive a radio frequency (RF) signal;
a signal processor to process and to convert the RF signal received from the antenna into a baseband signal;
an antenna connector to interconnect the antenna and the signal processor; and
a connection check part to check whether the antenna is connected properly and to output a connection check signal.

12. The wireless communication module as claimed in claim 11, wherein the connection check part is connected to an RF signal line through which the RF signal received at the antenna is transmitted to the signal processor, and the connection check part outputs the connection check signal according to an opening or a grounding of the RF signal line.

13. The wireless communication module as claimed in claim 12, further comprising a coaxial cable through which the antenna transmits the RF signal to the signal processor, wherein the coaxial cable comprises the RF signal line and a ground line.

14. The wireless communication module as claimed in claim 12, wherein:
if the antenna is not connected properly, the RF signal line is opened, the connection check part is turned on, and the connection check signal is output at a first level; and
if the antenna is connected properly, the RF signal line is grounded, the connection check part is turned off, and the connection check signal is output at a second level opposite the first level.

15. The wireless communication module as claimed in claim 11, wherein the signal processor comprises an RF circuit which is connected with the antenna, and transmits and receives the RF signal.

16. The wireless communication module as claimed in claim 15, wherein the signal processor further comprises a baseband MAC circuit to process and to convert the RF signal received from the RF circuit into the baseband signal.

17. The wireless communication module as claimed in claim 16, wherein the connection check part outputs the connection check signal to the baseband MAC circuit, and the baseband MAC circuit transmits the connection check signal to an external host through a host interface.

18. The wireless communication module as claimed in claim 11, further comprising:
a host interface to communicate data with an external host,
wherein the connection check signal is provided to the external host through the host interface by way of the signal processor.

19. The wireless communication module as claimed in claim 11, wherein the connection check signal is provided to external host through a signal output pin connected to the external host.

20. A method of controlling a wireless communication apparatus which comprises an antenna to transmit and/or to receive a radio frequency (RF) signal, a signal processor to process and to convert the RF signal received from the antenna into a baseband signal, an antenna connector to interconnect the antenna and the signal processor, and a system part to receiving and to process the baseband signal, the method comprising:
outputting a connection check signal with respect to a connection of the antenna according to an opening or a grounding of an RF signal line through which the RF signal received at the antenna is transmitted to the signal processor; and
receiving, by the system part, the connection check signal and executing a predetermined routine according to whether the antenna is connected.

21. The method as claimed in claim 20, wherein the system part comprises a display part, and
the executing of the predetermined routine comprises controlling to display a message indicating whether the antenna is connected on the display part.

22. The method as claimed in claim 20, wherein the outputting of the connection check signal comprises:
outputting the connection signal at a first level if the antenna is not connected properly and the RF signal line is opened; and
outputting the connection signal at a second level opposite the first level if the antenna is connected properly and the RF signal line is grounded.

23. The method as claimed in claim 20, wherein the receiving, by the system part, of the connection signal comprises providing the connection check signal through a host interface from the signal processor to the system part.

24. The method as claimed in claim 20, wherein the receiving, by the system part, of the connection signal comprises providing the connection check signal through a signal output pin connected to the system part.
